(19) United States
(12) Patent Application Publication
(10) Pub. No.: US 2016/0349307 A1
(43) Pub. Date: Dec. 1, 2016

(54) ELECTRONIC COMPONENT HAVING FUNCTION TO DETECT MANUFACTURING DEFECTS OR DAMAGE/DEGRADATION AND PRINTED WIRING BOARD

(71) Applicant: FANUC Corporation, Yamanashi (JP)

(72) Inventors: Takaaki KOMATSU, Yamanashi (JP); Yasumichi SAKODA, Yamanashi (JP)

(21) Appl. No.: 15/166,216

(22) Filed: May 26, 2016

(30) Foreign Application Priority Data
May 27, 2015 (JP) 2015-107496

(51) Int. Cl. G01R 31/04; H03K 19/20; H05K 1/18; H03K 3/037

(52) U.S. Cl. CPC G01R 31/041; H03K 3/037; H03K 19/20; H05K 1/181

(57) ABSTRACT

An electronic component having a plurality of terminals arranged on a bottom side of a package and mounted on a printed wiring board includes at least one detection terminal as a portion of the plurality of terminals, the detection terminal being connected to a ground outside the electronic component, wherein the detection terminal is connected to an input port of an input buffer and one end of a resistor inside the electronic component, the other end of the resistor is connected to a power supply, and the input buffer detects a poor connection of a solder joint or a socket by outputting a first binary signal obtained by binarizing a voltage level input into the input buffer using a predetermined threshold.

### BACKGROUND OF THE INVENTION

1. Field of the Invention

The present invention relates to an electronic component having a function to detect soldering defects, damage, or degradation of a solder joint with a board or a poor connection of a socket. The invention also relates to a printed wiring board on which the electronic component is mounted.

2. Description of the Related Art

The present invention relates to an electronic component having a function to detect soldering defects, damage, or degradation of a solder joint with a board or a poor connection of a socket. The invention also relates to a printed wiring board on which the electronic component is mounted.

When an electronic component of a package such as BGA (Ball Grid Array), LGA (Land Grid Array), and CSP (Chip Size Package) mounted on a printed wiring board is subject to temperature stress or vibration/impact or the board is warped, it is known that a large stress tends to apply to corner terminals and nearby terminals of the electronic component. If such a physical stress applies continuously for a long period of time, a solder joint of a corner terminal of an electronic component will sooner or later crack. If a terminal of an electronic component cracks, the system may go down and thus, it is necessary to take some measures.

As the simplest measure, a technique of adopting a GND terminal or a power terminal, each of which is present more than one terminal, for a corner terminal or a terminal in the neighborhood thereof so that the crack thereof does not directly lead to a malfunction is known.

As a technique of detecting a poor connection of a terminal of an electronic component, a technique of determining a poor connection of a terminal connected to a pull-up resistor outside based on a potential of an internal terminal by pulling down the potential by a transistor having a larger ON resistor inside the component is disclosed (JP 10-011558 A). Here, instead of a dummy terminal for detection, for example, a reset terminal actually used for system operation is assumed as a terminal to be inspected.

Also, a method of detecting soldering defects of an IC terminal using a terminal pulled up inside an electronic component is disclosed (JP 07-218582 A). A detection circuit is arranged on a board outside electronic components.

A system down due to a crack in corner terminals can be prevented by assigning corner terminals to a GND or a power supply, each of which is present more than one terminal and a crack in those terminals does not directly affect the system operation. However, there is no way of knowing an occurrence of crack, and if degradation advances by further stress, terminals other than corner terminals may crack and the system may go down.

Also, according to the technique disclosed by JP 10-011558 A, a component is needed outside and an external terminal is driven by a pull-up resistor and thus, the impedance is high and a malfunction may occur in an FA environment or the like under the influence of noise. Further, according to the technique disclosed by JP 07-218582 A, a detection circuit needs to be provided outside, leading to an increase in cost.

### SUMMARY OF THE INVENTION

The present invention is made in view of the above circumstances and an object thereof is to provide a printed wiring board and an electronic component having a function to detect a poor connection of a solder joint between the electronic component and the printed wiring board from the initial stage without needing an external circuit.

An electronic component according to the present invention having a plurality of terminals arranged on a bottom side of a package and mounted on a printed wiring board includes at least one detection terminal as a portion of the plurality of terminals, the detection terminal being connected to a ground outside the electronic component, wherein the detection terminal is connected to an input port of an input buffer and one end of a resistor inside the electronic component, the other end of the resistor is connected to a power supply, and the input buffer outputs a first binary signal obtained by binarizing a voltage level input into the input buffer using a predetermined threshold.

Also an electronic component according to the present invention having a plurality of terminals arranged on a bottom side of a package and mounted on a printed wiring board includes at least one detection terminal as a portion of the plurality of terminals, the detection terminal being connected to a power supply outside the electronic component, wherein the detection terminal is connected to an input port of an input buffer and one end of a resistor inside the electronic component, the other end of the resistor is connected to a ground, and the input buffer outputs a first binary signal obtained by binarizing a voltage level input into the input buffer using a predetermined threshold.

The electronic component further includes a latch circuit into which the first binary signal output by the input buffer is input, wherein the latch circuit outputs a second binary signal, outputs a first level as the second binary signal while the first binary signal input from the input buffer is at the first level, and retains output of a second level of the latch circuit after the first binary signal output by the input buffer once outputs the second level.

The electronic component further includes a reset input terminal, wherein when a reset signal is input from the reset input terminal, the latch circuit is initialized.

A printed wiring board on which the above electronic component is mounted is characterized in that at least one pad to which the detection terminal of the electronic component is soldered is different in area or shape from the pads to which other terminals of the electronic component are soldered. In accordance with the present invention, on the printed wiring board on which the electronic component is mounted, it will be possible to estimate stress to the electronic component by making at least one of the detection terminals easier to crack than other signal terminals.

This can be realized by making a pad of the detection terminals smaller than pads of other signal terminals, or making a shape of a pad of the detection terminals different from shapes of pads of other signal terminals.

According to the present invention, a printed wiring board and an electronic component having a function capable of detecting a poor connection of a solder joint between the electronic component and the printed wiring board from the initial stage without needing an external circuit can be provided.

### BRIEF DESCRIPTION OF THE DRAWINGS

The above object and other objects of the present invention will be apparent from the description below with reference to appended drawings. Among these drawings:

FIG. 1 is a diagram showing that a plurality of terminals are arranged at the bottom of an electronic component as BGA;

FIG. 2A is a diagram showing an arrangement example of detection terminals at the bottom of the electronic component (part 1);

FIG. 2B is a diagram showing an arrangement example of detection terminals at the bottom of the electronic component (part 2);

FIG. 2C is a diagram showing an arrangement example of detection terminals at the bottom of the electronic component (part 3);

FIG. 2D is a diagram showing an arrangement example of detection terminals at the bottom of the electronic component (part 4);

FIG. 2E is a diagram showing an arrangement example of detection terminals at the bottom of the electronic component (part 5);

FIG. 2F is a diagram showing an arrangement example of detection terminals at the bottom of the electronic component (part 6);

FIG. 3A is a diagram showing a configuration of a detection circuit according to a first embodiment of the present invention and shows a normal solder joint without a crack between a detection terminal and a pad;

FIG. 3B is a diagram showing the configuration of the detection circuit according to the first embodiment of the present invention and shows a solder joint crack between the detection terminal and the pad;

FIG. 3C is a cross-section diagram showing a printed wiring board provided with the pad;

FIG. 4A is a diagram showing another configuration of the detection circuit according to the first embodiment of the present invention and shows a normal solder joint without a crack between the detection terminal and the pad;

FIG. 4B is a diagram showing the other configuration of the detection circuit according to the first embodiment of the present invention and shows a solder joint crack between the detection terminal and the pad;

FIG. 5A is a diagram showing still another configuration of the detection circuit according to a second embodiment of the present invention and shows a normal solder joint without a crack between the detection terminal and the pad;

FIG. 5B is a diagram showing still the other configuration of the detection circuit according to the second embodiment of the present invention and shows a solder joint crack between the detection terminal and the pad;

FIG. 6 is a diagram showing Example 1 of a latch circuit that retains 1 if 1 is input even for a moment;

FIG. 7 is a diagram showing Example 2 of the latch circuit that retains 1 if 1 is input even for a moment;

FIG. 8 is a diagram showing Example 3 of the latch circuit that retains 0 if 0 is input even for a moment;

FIG. 9 is a diagram showing Example 4 of the latch circuit that retains 0 if 0 is input even for a moment;

FIG. 10A is a diagram showing an example of a footprint of the printed wiring board and a diagram showing that the size of a pad to which a detection terminal is soldered is smaller than that of a pad to which another terminal is connected; and

FIG. 10B is a diagram showing an example of the footprint of the printed wiring board and a diagram showing an embodiment in which pad sizes are changed stepwise.

### DETAILED DESCRIPTION OF THE PREFERRED EMBODIMENTS

Hereinafter, the embodiments of the present invention will be described together with the drawings. The same reference signs are used for components having similar functions in different embodiments to provide the description below.

### First Embodiment

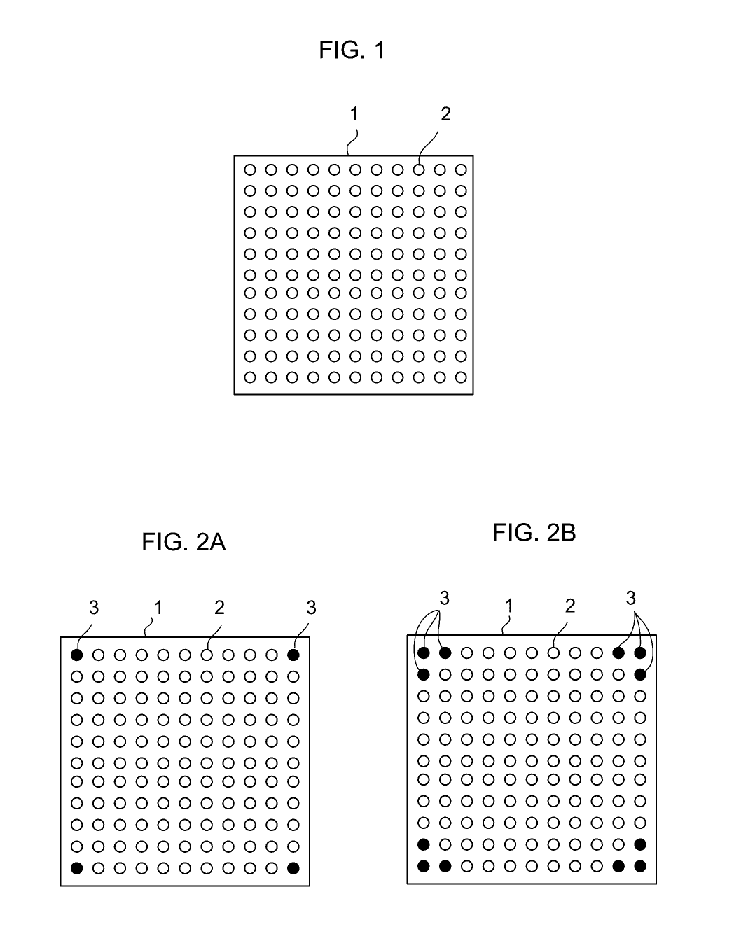

The first embodiment to carry out the present invention will be described using FIGS. 1 to FIGS. 3C. FIG. 1 illustrates the arrangement of a plurality of terminals 2 on a bottom side of a package of an electronic component 1 as BGA. The electronic component 1 is a component of the package such as BGA, LGA, or CSP.

If the electronic component 1 is BGA, the terminal 2 is constructed as an electrode (called a bump) formed in a semispherical shape for terminals arranged in a grid pattern at the bottom of the package. Hereinafter, a terminal formed in a semispherical shape will simply be called the terminal 2. A printed wiring board 11 is provided with a pad 9. Each of the terminals 2 of the electronic component 1 is soldered to the pad 9 to mount the electronic component 1 on the printed wiring board 11. The pad 9 has a circular shape here, but may also have other shapes.

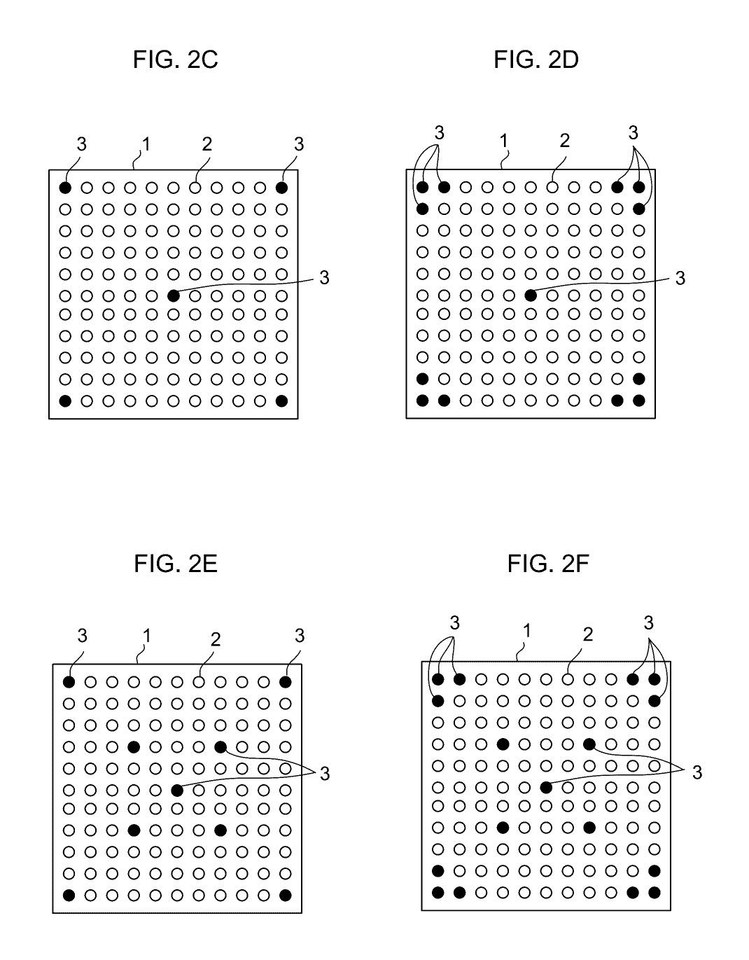

Some of the terminals 2 of the electronic component 1 are configured to be used as detection terminals 3 to detect a poor connection to a printed wiring board on which the electronic component 1 is mounted. Any number of the detection terminals 3 may be placed in any locations of the plurality of terminals 2 provided in the electronic component 1. As shown in FIGS. 2A to 2F, the detection terminals 3 are desirably located on the corners, among the plurality of terminals 2 arranged in a grid pattern at the bottom of the electronic component 1. This is because the terminal 2 on a corner is more likely to be degraded and damaged due to vibration or impact than the terminals 2 arranged in other locations. Further, by providing the detection terminal 3 in the terminals 2 other than those on the outer circumference, for example, in the center of the electronic component 1, a poor connection (particularly, mounting defects during production) of the terminal 2 in a position for which it is difficult to conduct a visual inspection can also be detected.

In FIG. 2A, one terminal is used for each of the four corners as the detection terminal 3. In FIG. 2B, three terminals are used for each of the four corners as the detection terminals 3. In FIG. 2C, one terminal is used for each of the four corners as the detection terminal 3, and additionally, one terminal in the center is used as the detection terminal 3. In FIG. 2D, three terminals are used for each of the four corners as the detection terminals 3 and further, one terminal in the center is used as the detection terminal 3. In FIG. 2E, one terminal is used for each of the four corners as the detection terminal 3 and further, the five terminals inside for which it is difficult to conduct a visual inspection as the detection terminal 3. In FIG. 2F, three terminals are used for each of the four corners as the detection terminals 3 and further, five terminals inside for which it is difficult to conduct a visual inspection as the detection terminal 3.

From the viewpoint of detecting mounting defects of the electronic component 1 during production of the printed wiring board 11, it is also effective to adopt inside terminals as well as corner terminals as the detection terminals 3. It is difficult to visually check a connection of the terminal 2 inside, but mounting defects can easily be detected by the technique in the present invention without additional costs. Incidentally, the electronic component 1 may directly be soldered to the printed wiring board 11 or may be mounted thereon via a socket or the like.

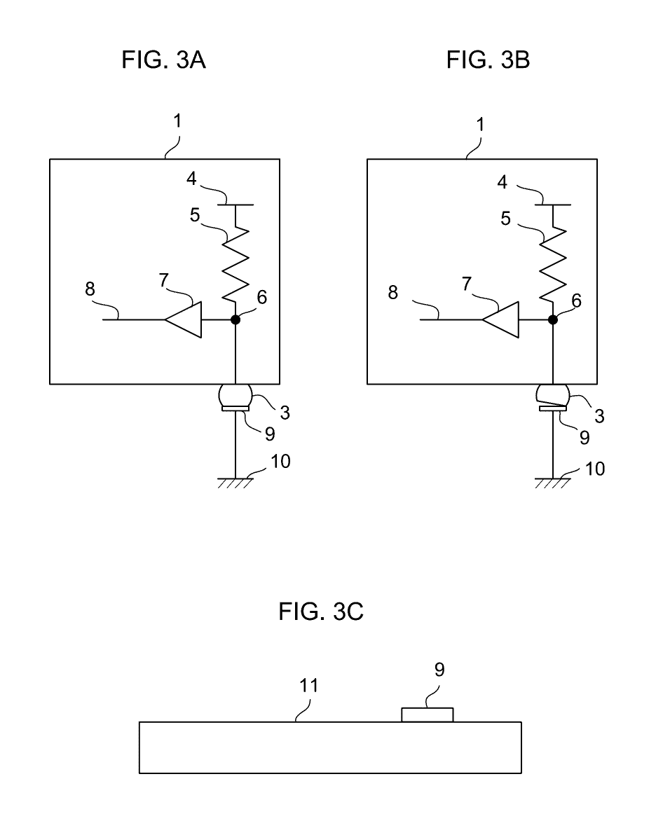

FIGS. 3A to 3C are diagrams showing the configuration of a detection circuit according to the first embodiment of the present invention. FIG. 3A shows a normal solder joint without a crack between the detection terminal 3 and the pad 9. FIG. 3B shows a solder joint crack between the detection terminal 3 and the pad 9. FIG. 3C is a cross-section diagram showing the printed wiring board 11 provided with the pad 9.

The detection terminal 3 is soldered to the pad 9 on the printed wiring board 11 and is electrically connected to a GND 10 directly or via a resistor (not shown). The detection terminal 3 is also connected to an input buffer 7 in which a resistor 5 is connected to an input terminal 6 inside the electronic component 1 and the other end of the resistor 5 is connected to a power supply 4. The resistor 5 is a pull-up resistor. The power supply 4 is a power supply used to supply power the circuits inside the electronic component 1. The voltage of the power supply 4 can be 5 V, 3.3 V, 2.5 V, 1.8 V, 1.5 V, 1 V or the like for example.

The input buffer 7 compares a predetermined voltage threshold and the voltage level input into the input buffer 7 and outputs 0 (or 1) to OUTPUT 8 if the input voltage into the input buffer 7 is lower than the threshold and outputs 1 (or 0) if the input voltage is higher than the threshold. That is, a binary signal is output in accordance with the voltage level input into the input buffer 7. In this case, if the connection of the electronic component 1 and the printed wiring board 11 (pad 9) is normal, the output is 0 (or 1), and if 1 (or 0) is output from the OUTPUT 8, the connection is determined to be abnormal.

In the development of electronic components such as FPGA, gate arrays, and cell base IC, input buffers and bidirectional buffers with such an internal pull-up resistor are usually selectable as standard I/O cells provided by semiconductor manufacturers. In most cases, therefore, a mounting defect detection circuit as shown in FIGS. 3A and 3B can be easily incorporated into electronic components such as FPGA, gate arrays, and cell base IC without additional costs.

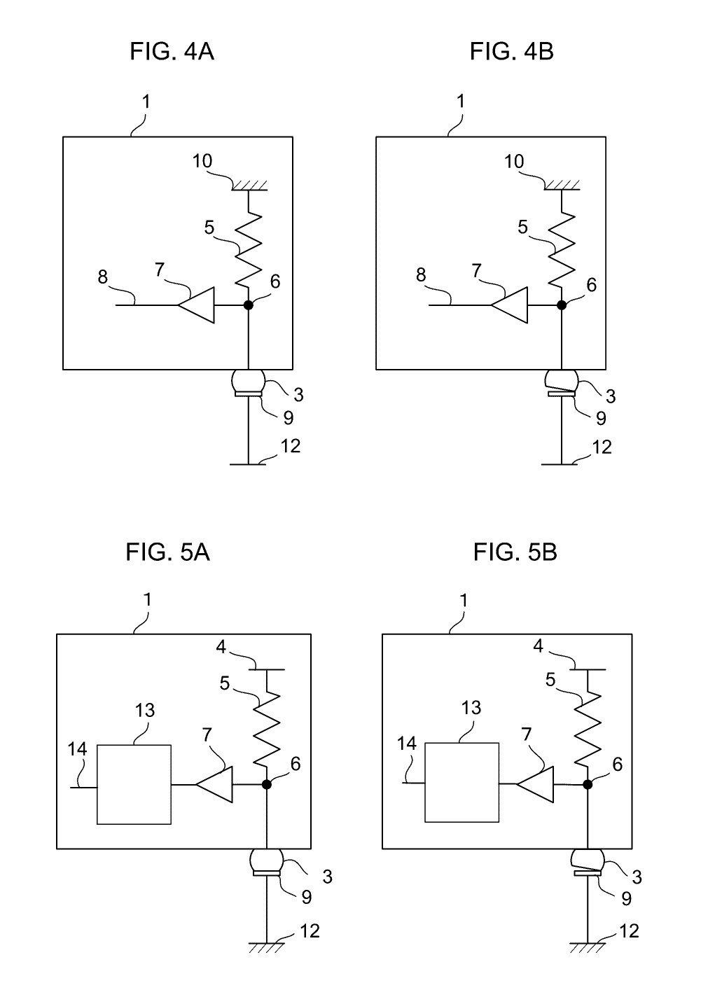

FIGS. 4A and 4B are diagrams showing another configuration of the detection circuit according to the first embodiment of the present invention. FIG. 4A shows a normal solder joint without a crack between the detection terminal 3 and the pad 9. FIG. 4B shows a solder joint crack between the detection terminal 3 and the pad 9.

The detection terminal 3 is connected to a power supply 12 on the printed wiring board 11 directly or via a resistor (not shown). The power supply 12 is present on the printed wiring board 11 and is, for example, 5 V, 3.3 V, 2.5 V, 1.8 V, 1.5 V, 1 V or the like. The detection terminal 3 is connected to the input buffer 7 in which the resistor 5 is connected to the input terminal 6 inside the electronic component 1 and the other end of the resistor 5 is connected to the GND 10. The GND 10 may be installed outside or inside the electronic component 1. The input buffer 7 compares a predetermined voltage threshold and the voltage level input into the input buffer 7 and outputs 0 (or 1) to OUTPUT 8 if the input voltage into the input buffer 7 is lower than the threshold and outputs 1 (or 0) if the input voltage is higher than the threshold. In this case, if the connection of the electronic component 1 and the printed wiring board 11 is normal, 1 (or 0) is output and if 0 (or 1) is output to the OUTPUT 8, the connection is determined to be abnormal.

In the development of electronic components such as FPGA, gate arrays, and cell base IC, input buffers and bidirectional buffers with such an internal pull-down resistor may be selectable as standard I/O cells provided by semiconductor manufacturers. In such a case, a mounting defect detection circuit as shown in FIGS. 4A and 4B can easily be incorporated without additional costs.

### Second Embodiment

The basic configuration of the second embodiment of the present invention is the same as that of the first embodiment. FIGS. 5A and 5B are diagrams showing the configuration of the detection circuit according to the second embodiment of the present invention. FIG. 5A shows a normal solder joint without a crack between the detection terminal 3 and the pad 9. FIG. 5B shows a solder joint crack between the detection terminal 3 and the pad 9.

The electronic component 1 further includes a latch circuit 13, wherein a first binary signal (binarized signal) output by the input buffer 7 is input into the latch circuit 13 and the latch circuit 13 outputs a second binary signal (binarized signal), outputs a first level as the second binary signal while the first binary signal input from the input buffer 7 is at the first level, outputs a second level when the first binary signal changes to the second level, and continues to output the second level after outputting the second level once even if the first binary signal reverts to the first level from the second level. By providing the latch circuit, an occurrence of a poor connection even for a moment can be detected.

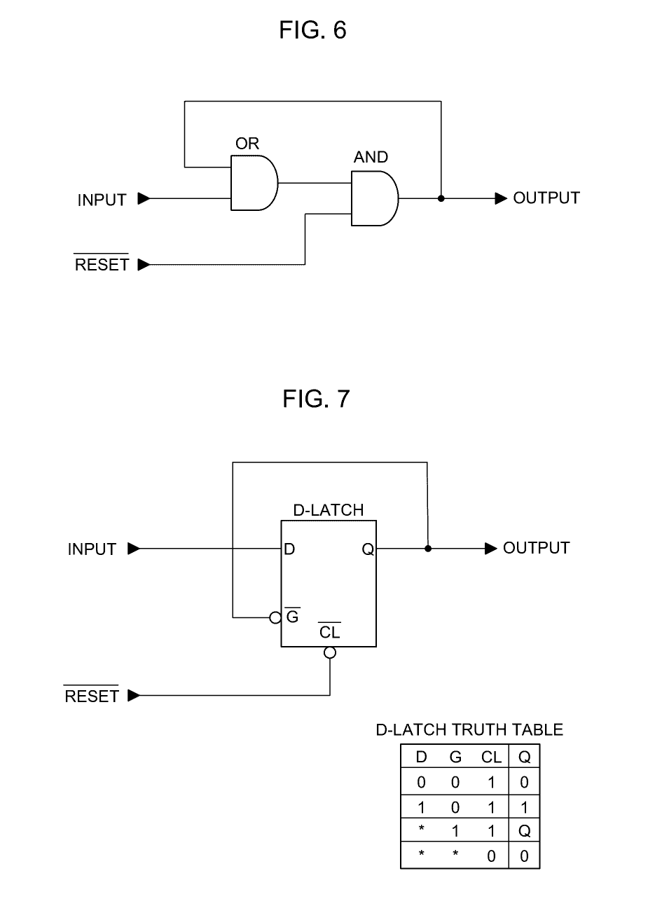

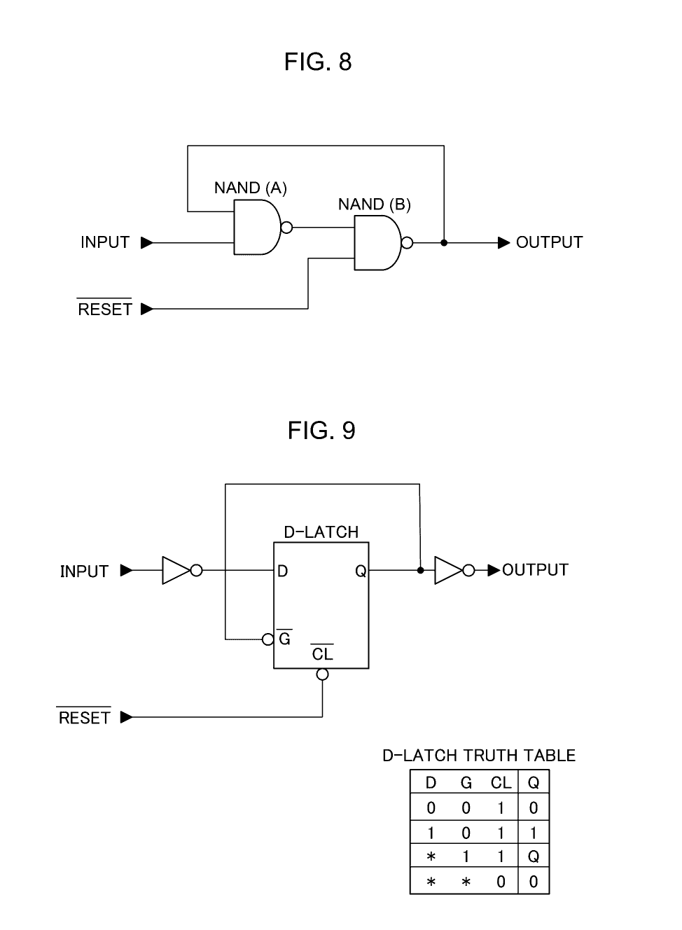

As described above, subsequent to the input buffer 7, the latch circuit 13 that latches the output of the input buffer 7 is provided. The output of the latch circuit 13 is assumed to be OUTPUT 14. Examples of the latch circuit 13 that retains 1 if 1 is input even for a moment are shown in FIGS. 6 and 7. Examples of the latch circuit 13 that retains 0 if 0 is input even for a moment are shown in FIGS. 8 and 9.

FIG. 6 is a diagram showing Example 1 of the latch circuit that retains 1 if 1 is input even for a moment. In the initial state, output OUTPUT of the latch circuit is 0. As described below, the latch circuit is initialized when a RESET input becomes 0. Under normal conditions, 1 is input from RESET into an AND gate and 0 is input from INPUT into an OR gate. Both inputs of the OR gate are 0 and thus, the output of the OR gate is 0 and 0 is input into the AND gate. Therefore, the output of the AND gate is 0 and the output OUTPUT is 0.

Here, if 1 is input from INPUT into the OR gate, the output of the OR gate is 1. Thus, both inputs of the AND gate are 1 and the output of the AND gate is 1. That is, the output OUTPUT of the latch circuit is 1. Even if the input from INPUT changes to 0 subsequently, the output of the OR gate remains to be 1 because the output 1 of the AND gate is input into the OR gate. Thus, both inputs of the AND gate remain to be 1 and the output of the AND gate retains 1. Therefore, if 1 is input from INPUT even for a moment, OUTPUT is 1 and the latch circuit in FIG. 6 retains 1.

In the latch circuit in FIG. 6, when the RESET input becomes 0, the output of the AND gate is 0 and the value of OUTPUT is initialized to 0.

FIG. 7 is a diagram showing Example 2 of the latch circuit that retains 1 if 1 is input even for a moment. Here, a D latch cell is used as a circuit element. Q output of the D latch is fed back to G control input of the D latch and thus, when the Q output of the D latch once becomes 1, the value of the Q output remains to be 1 even if the value of the D input changes. Accordingly, the latch circuit in FIG. 7 retains 1 as OUTPUT if 1 is input from INPUT even for a moment.

FIG. 8 is a diagram showing Example 3 of the latch circuit that retains 0 if 0 is input even for a moment. In the initial state, the output OUTPUT of the latch circuit is 1. As described below, the latch circuit is initialized when the RESET input becomes 0. Under normal conditions, 1 is input from RESET into a NAND(B) gate and 1 is input from INPUT into a NAND(A) gate. Both inputs of the NAND(A) gate are 1 and thus, the output of the NAND(A) gate is 0 and 0 is input into the NAND(B) gate. Therefore, the output of the NAND(B) gate is 1 and the output OUTPUT is 1.

Here, if 0 is input from INPUT into the NAND(A) gate, the output of the NAND(A) gate is 1. Therefore, both inputs of the NAND(B) gate are 1 and the output of the NAND(B) gate is 0. That is, the output OUTPUT of the latch circuit is 0. Even if the input from INPUT subsequently changes to 1, the output 0 of the NAND(B) gate is input into the NAND(A) gate and thus, the output of the NAND(A) remains to be 1. Therefore, both inputs of the NAND(B) gate remain to be 1 and the output of the NAND(B) gate retains 0. Accordingly, if 0 is input from INPUT even for a moment, OUTPUT is 0 and the latch circuit in FIG. 8 retains 0.

In the latch circuit in FIG. 8, when the RESET input becomes 0, the output of the NAND(B) gate is 1 and the value of OUTPUT is initialized to 1.

FIG. 9 is a diagram showing Example 4 of the latch circuit that retains 0 if 0 is input even for a moment. Here, a D latch cell is used as a circuit element. Q output of the D latch is fed back to G control input of the D latch and thus, when the Q output of the D latch once becomes 1, the value of the Q output remains to be 1 even if the value of the D input changes. Accordingly, if 0 is input from INPUT even for a moment, the latch circuit in FIG. 9 retains 0 as OUTPUT.

When cracks of a solder joint between the electronic component 1 and the printed wiring board 11 arise due to vibrations or the like that occur continuously for a long period of time, even if cracks arise once, the solder joint may be electrically connected sometimes and isolated at other times. Thus, by providing the latch circuit 13 after the input buffer 7, if conditions of a poor connection arise in the detection terminal 3 even once, such conditions can be detected and cracks can be reliably detected in the initial stage. Accordingly, measures such as replacing the printed wiring board 11 can be taken before a malfunction occurs.

### Third Embodiment

The basic configuration of the third embodiment is the same as that of the first embodiment. The electronic component is assumed to be configured by including a reset terminal in one of the terminals. When the reset terminal is asserted from outside (when a reset signal is input), the latch circuit is initialized.

### Fourth Embodiment

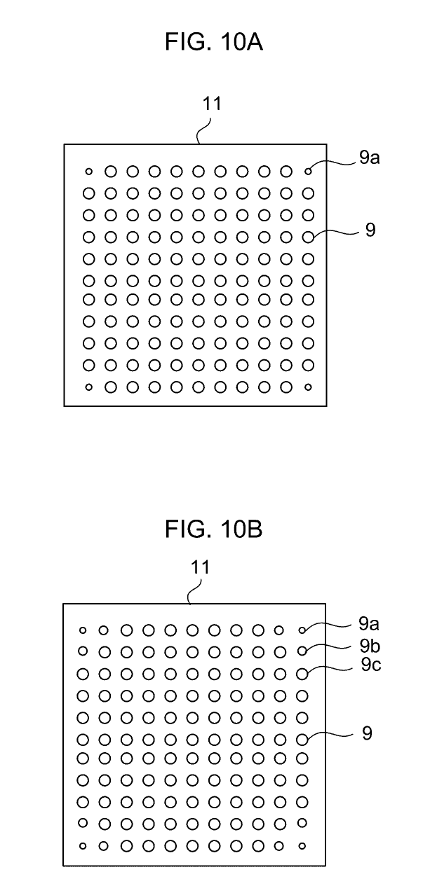

The electronic component 1 described above is mounted on the printed wiring board 11. In the printed wiring board 11 on which the electronic component 1 is mounted, a pad for the detection terminal 3 can be made smaller (in diameter) than pads for other terminals so that the detection terminal 3 tends to crack earlier than other terminals (see FIG. 10A). In FIG. 10A, the size of a pad 9a to which the detection terminal 3 is soldered is smaller than that of the pads 9 to which the other terminals 2 are connected (9>9a).

When the size of the pad 9 is changed stepwise (see FIG. 10B), the level of degradation can be detected. A pad 9c tends to degrade earlier than a pad 9b, and the pad 9b tends to degrade earlier than a pad 9c. Though not illustrated, not the size but the shape of the pads 9 can be changed so that the detection terminal tends to crack earlier than other terminals. This is because the solder joint can be made less reliable by adopting a quadrangular, triangular, polygonal, or doughnut shape as the shape of the pad 9 so that degradation of the solder joint may be speeded up. In the embodiment that the pads are provided on the electronic component, the pads can also be varied in their size and/or shape.

In the foregoing, the embodiments of the present invention have been described, but the present invention is not limited to the above embodiments and can be carried out in other embodiments by making appropriate changes.

1. An electronic component having a plurality of terminals arranged on a bottom side of a package and mounted on a printed wiring board, the electronic component comprising
at least one detection terminal as a portion of the plurality of terminals, the detection terminal being connected to a ground outside the electronic component, wherein
the detection terminal is connected to an input port of an input buffer and one end of a resistor inside the electronic component,
the other end of the resistor is connected to a power supply, and
the input buffer outputs a first binary signal obtained by binarizing a voltage level input into the input buffer using a predetermined threshold.

2. An electronic component having a plurality of terminals arranged on a bottom side of a package and mounted on a printed wiring board, the electronic component comprising
at least one detection terminal as a portion of the plurality of terminals, the detection terminal being connected to a power supply outside the electronic component, wherein
the detection terminal is connected to an input port of an input buffer and one end of a resistor inside the electronic component,
the other end of the resistor is connected to a ground, and
the input buffer outputs a first binary signal obtained by binarizing a voltage level input into the input buffer using a predetermined threshold.

3. The electronic component according to claim 1, further comprising
a latch circuit into which the first binary signal output by the input buffer is input, wherein
the latch circuit outputs a second binary signal, outputs a first level as the second binary signal while the first binary signal input from the input buffer is at the first level, and retains output of a second level after the first binary signal output by the input buffer once becomes the second level.

4. The electronic component according to claim 3, further comprising
a reset input terminal, wherein
when a reset signal is input from the reset input terminal, the latch circuit is initialized.

5. A printed wiring board on which the electronic component according to claim 1 is mounted is characterized in that
at least one pad to which the detection terminal of the electronic component is soldered is different in its area or shape from the pads to which other terminals of the electronic component are soldered.
